(19) United States
(12) Patent Application Publication
(10) Pub. No.: US 2009/0139567 A1
(43) Pub. Date: Jun. 4, 2009

(54) CONFORMAL PROTECTIVE COATING FOR SOLAR PANEL

(76) Inventors: Philip Chihchau Liu, Fremont, CA (US); Marvin S. Keshner, Sonora, CA (US); Paul McClelland, Monmouth, OR (US); Donald Winston Rice, San Jose, CA (US); Rajeewa Arya, Beaverton, OR (US)

Correspondence Address: WEISS & MOY PC, 4204 NORTH BROWN AVENUE, SCOTTSDALE, AZ, 85251, US

(21) Appl. No.: 11/947,543

(22) Filed: Nov. 29, 2007

(51) Int. Cl. H01L 31/0216; B05D 5/12

(52) U.S. Cl. 136/256; 427/74

(57) ABSTRACT

A multilayer conformal coating is optimized in both composition and geometry to protect the back and sides of a transparent-fronted thin-film solar photovoltaic panel or similar device from various damage mechanisms associated with long-term outdoor exposure without an additional backcap or edge frame. A “barrier stack” or “barrier layer” of inorganic moisture-barrier and chemical-barrier layers is applied to the back of the photovoltaic functional film stack, extending into a bare-substrate border zone around the functional stack edges. The barrier stack shields the functional stack from moisture and chemical invasion, and the coated border zone effectively seals the vulnerable edges of the functional stack. An “envelope stack” or “envelope layer” of thicker polymer films is applied over the mechanically delicate inorganic barrier stack and around the solar photovoltaic panel edges. The envelope stack electrically insulates the solar photovoltaic panel and substantially protects the panel back and sides from mechanical shock, stress, and abrasion, thermal stress, fire, weathering, and UV-exposure degradation.

### BACKGROUND OF THE INVENTION

This invention relates to optoelectronic devices installed outdoors, particularly those that include photovoltaic cells for converting sunlight or other light into electricity (collectively, “solar panels”). Such devices require protection from the multiple types of damage that can result from years of outdoor exposure. This invention also relates to multilayer protective coatings that include both polymer and inorganic layers.

The cost of solar energy production can be reduced in three major ways: by increasing the energy conversion efficiency of solar cells, by lowering the production cost of cells and the panels that contain them, and by increasing their useful life. This invention is directed toward lowering production costs, increasing the useful life of the solar panels, and lowering the total cost of operation by reducing the need for costly repairs and replacements over time.

Most often, solar panels are installed outdoors, where they are most likely to capture direct sunlight, away from any shelter that would also produce shade. Hence, one significant limit on their useful life is the accumulation of damage from exposure to the elements. The optical and electronic components can be damaged, reducing their efficiency and safety, by moisture, chemical contaminants, mold, and bacteria; mechanical shocks, impacts, and abrasion; mechanical fatigue from repeated cycles of temperature and stress; electrical surges from lightning strikes; and gradual chemical degradation from the ultraviolet (UV) components of the very sunlight necessary for their operation.

Corrosion of common solar-panel materials can be accelerated by moisture, and by chemically active pollutants that may be present in outdoor air such as chlorine, sulfur compounds, oxides of nitrogen, and salts. In conductive materials, currents flowing through high-electrochemical-potential contact interfaces (such as copper-to-aluminum) can create significant ionic currents that also encourage corrosion. Therefore, solar panels typically include one or more protective layers that protect the materials necessary to generate electricity from sunlight from degrading in performance over time in an outdoor environment.

Under the constant onslaught of the elements over time, even pinhole-sized defects in protective layers can provide ingress paths for moisture and contaminants that eventually cause internal corrosion and degrade solar-panel performance. Depositing perfectly pinhole-free coatings is very difficult, especially on a large substrate, and many solar panels have dimensions larger than 1 meter. Some materials, such as silicon and aluminum, “self-passivate” by forming stable oxides at any boundary with air, including the inner edges of pinholes. Other materials tend to inhibit pinhole formation. However, self-passivating or pinhole-inhibiting materials do not always have the best protective qualities.

Solar panels must also operate safely. National and international quality and safety organizations, such as Underwriters' Laboratories (UL) and the International Electrotechnical Commission (IEC) have devised standards for solar panels that require efficient and safe performance under a variety of rigorous test conditions intended to simulate prolonged outdoor exposure. Electrical insulation and flame retardance are required, as well as thermal and mechanical resilience and resistance to moisture, corrosion, abrasion, impacts, fungus, bacteria, prolonged UV irradiation, and general weathering.

Every part of a solar panel requires protection from the elements. Typically, sunlight enters through the one surface of a solar panel and is captured by light sensitive layers beneath this surface that convert the sunlight to electricity. The protective layers between the sunlight and the light-sensitive layers must be highly transparent to the useful wavelengths of the solar spectrum, while protective layers over other parts of the panel need not be transparent. Because the added requirement of high transparency tends to increase the cost of protective layers, it is common practice to use different protection means for the light-receiving and non-light-receiving parts of the panel.

In most solar panels, the sunlight enters only one side of the panel (the “front”) and the converted electricity exits the opposite side (the “back”). FIG. 1 is a schematic cross-section of a prior-art solar panel. Light from sun 100 passes through front skin, faceplate, or substrate (depending on how the panel is made) 110 and impinges on functional stack 120, where it is converted to electricity. The functional stack typically includes a transparent front conductor, a light-converting layer, and a back conductor. The light-converting layer can be a film of amorphous silicon, cadmium telluride, copper indium gallium di-selenide, nano-particles, or other light-converting materials, or it can be a thin slice or sheet of a single-crystal or polycrystalline semiconductor or other solid light-converting material. The electrical output is collected at one or more electrical contacts 130 on the back of the panel.

A backskin or backcap 140, made of glass or of laminates that may include polymer layers, glassy layers, and metal layers, protects the back of the panel. These backskins and backcaps are expensive, and special care must be taken not to damage them during shipping or storage before they are assembled into finished panels and fixed in place with encapsulant 150. (Encapsulant 150 is usually a polymer such as ethylene vinly acetate (EVA). As these polymers completely encapsulated many of the earlier wafer-based solar cells, the solar industry continues to call them “encapsulants” even when, as in this example, they do not fully encapsulate a device). Conductive leads 160 from the prior-art panels typically come out through encapsulant 150 and holes 170 in backskin or backcap 140, into a junction box 180 attached to the outside of the panel. Once conductive leads 160 are in place, junction box 180 is filled with potting material or sealant (not shown). The DC power produced by the solar panel is coupled outside of the solar panel through the conductive leads 160 to junction box 180, and then either to a power inverter 190 to convert DC electrical power to AC, to a battery for energy storage, or to the terminal of another solar panel. The edges of prior-art solar panels are usually protected by a metal or metal-and-polymer frame 200, sometimes including rubber inserts and sealed to substrate by a sealant (often different from potting material or the sealant used injunction box 160). Because edge frame 200 and backskin or backcap 140 are separate parts, they must also be sealed at their juncture.

If either or both sealant is imperfectly applied or sustains damage in the field, the resulting seal breaches provide additional paths of ingress for moisture and contaminants. Some sealants and encapsulants 150 may chemically degrade over the operational life of a solar panel and produce contaminants themselves. Furthermore, the region between frame 200 and backcap 140, and the region between frame 200 and the front surface of substrate 1 10, can trap liquid water during diurnal cycles that cause water condensation. This liquid water in framed systems can accelerate device failure.

Prior-art backskins and backcaps are typically assembled into finished panels via one or more batch processes. Prior-art backskins, backcaps and encapsulants have to be cut to size and have holes punched before lamination. Lamination of backskins with encapsulant is typically a batch process. Compared to continuous processes, batch processes have the disadvantages of taking up more factory space, which increases overhead costs, and requiring entire batches to be scrapped if anything goes wrong with the process, which increases wastage costs.

The sealants and other polymers used in solar panels have high electrical resistance to block ionic currents, good mechanical strength and weathering resistance, and can be made fairly impervious to UV irradiation. When applied in thick layers (>50 μm), they enable a solar panel to withstand the high voltages (usually >2 kV) demanded by standard safety tests. However, the polymeric components of prior-art solar panels have several disadvantages. They often admit corrosion-promoting moisture and contaminants into the functional stack. The materials themselves are often permeable to water and chemicals. Ethylene-vinyl acetate (EVA), an encapsulant used extensively in prior-art solar panels generates by-products such as acetic acid when exposed to high temperature and humidity; these by-products corrode aluminum-based electrical contacts. EVA can also lose adhesion to bare glass when sodium ions diffuse out of the glass and moisture enters the interface; this adhesion loss can compromise electrical insulation. Glass manufacturers may apply barrier films to solar faceplates to block ion out-diffusion; however, the barrier layers are difficult for processing sensors to distinguish from the transparent electrode material applied directly over them. Therefore, panel manufacturers often inadvertently abrade away these barriers when they remove transparent electrode films from the edges of a glass panel faceplate to form a nonconductive border zone. When this happens, the EVA contacts the bare glass and is subject to delamination from ionic out-diffusion. In U.S. Pat. Nos. 5,478,402 and 5,476,553, Hanoka et al. laminate solar cells between ionomer sheets larger than the solar cells, then seal the sheets together around the edges of the cells. The ionomer sheets are better moisture barriers than more common polymers such as Tedlar® polyvinyl fluoride), and EVA, and this design significantly reduces the number of parts and seals required, but the ionomers add significant cost and the lamination is a batch process. Furthermore, a coating or skin made of an impermeable material may still have defects or be imperfectly sealed to the panel. Even an initially intact coating or skin may fatigue, degrade, or be damaged by exposure to the elements over time. If either of these events occurs, enough moisture or contaminants may enter, and enough corrosion or other damage result, to shorten the panel's useful life.

Because no single material readily available at reasonable cost provides all the different types of protection a solar panel needs, multiple protective layers are often used. Each layer may be made of a material that provides one or more types of protection, but need not provide them all. For instance, in U.S. Pat. No. 5,650,019, Yamada et al. deposit three different transparent polymer layers, each with a different protective property, on the front silicon layer of a solar cell that is fabricated on an aluminum substrate. Some of the desired protective properties, such as effective exclusion of moisture, are most commonly found in glassy materials, while others, such as mechanical resilience, are most commonly found in polymers. Coatings that comprise both glass and polymer layers in general are known. For example, in U.S. Pat. No. 5,439,849, McBride et al. coat an integrated-circuit (IC) device with several microns of polymer, overcoat the polymer with several hundred nanometers of glass, and optionally overcoat the glass with another polymer layer.

An additional advantage of multiple layers is that coating defects generally occur in random locations, and each layer can cover any defects in the layer below it. For example, in U.S. Pat. Nos. 6,866,901 and 7,005,798, Burrows et al. use layers of polymer as “decoupling layers” between layers of glass to fill in any pinhole defects in the glass layers of a protective coating for an organic light-emitting devices (OLED). OLEDs are another type of optoelectronic device enjoying increasing popularity for outdoor installation. However, OLEDs are much more sensitive to both moisture and oxygen than are most solar panels. This high sensitivity, sometimes coupled with a need for mechanical flexibility or highly planar surfaces, places demands on OLED encapsulation schemes that tend to increase production costs and fabrication difficulties. Because solar panels can be made less sensitive to very low levels of moisture and oxygen than OLEDs, these extra costs and complexities are not justified for solar-panel manufacture.

Accordingly, there has been a need for a novel To summarize, solar-panel technology would benefit from a means of protecting the panels from all the possible means of damage associated with long-term outdoor exposure, which would enable the panels to comply with the requirements for various quality and safety certifications, and which could be added to the panel by a continuous process for relatively low manufacturing cost. Because solar panels can be large (having meter-scale dimensions), the protection means should be scalable to articles of this size. The present invention fulfills these needs and provides other related advantages.

### BRIEF SUMMARY OF THE INVENTION

An object of this invention is to protect the back and edges of a solar panel from a wide variety of mechanical, chemical, electrical, thermal, biological, and irradiative damage mechanisms, thus prolonging the useful life of the solar panel and lowering the total cost of operation. Accordingly, the invention includes a multilayer conformal coating and a panel preparation process that combine to provide all these types of protection.

Another object of this invention is to overcome the disadvantages of the prior art by protecting the back and edges of a solar panel with materials that will not produce by-products that cause internal corrosion or other types of damage, and that are substantially impervious to by-products and other damaging effects that may be produced by other parts of the panel. Accordingly, the invention includes coatings directly adjacent to the photovoltaic functional stack and faceplate that substantially block, and are not harmed by, ions that may diffuse out of glass, and insulate current-carrying metallic components against corrosive ionic currents.

Another object of this invention is to produce a solar panel that can pass certification tests required by the applicable industrial quality and safety standards organizations. Accordingly, the geometry and arrangement of the coating layers are optimized for known, required test conditions which are reasonably believed to simulate long-term outdoor exposure.

Another object of this invention is to minimize the production cost of a large-area, durable solar panel with a long life expectancy. Accordingly, all of the component materials of the multilayer protective coating are readily available at low cost and may be applied by standard commercial methods as part of a continuous process.

Other features and advantages of the present invention will become apparent from the following more detailed description, taken in conjunction with the accompanying drawings which illustrate, by way of example, the principles of the invention.

### BRIEF DESCRIPTION OF THE DRAWINGS

The accompanying drawings illustrate the invention. In such drawings:

FIG. 1 is a cross-section of a prior-art solar panel assembly.

FIG. 2a is a simplified horizontal cross-section of an exemplary substrate and functional stack, illustrating a border zone around the edges or perimeter of the functional stack.

FIG. 2b is a simplified horizontal cross-section of the substrate and functional stack of FIG. 2a, illustrating a conductive connection tab bonded to an electrical contact on the functional stack.

FIG. 2c is a simplified horizontal cross-section of the assembly of FIGS. 2b, illustrating an inorganic barrier thin-film stack or layer applied over portions of the functional stack and the border zone.

FIG. 2d is a simplified horizontal cross-section of the assembly of FIG. 2c, illustrating a polymer envelope thick-film stack or layer applied over the inorganic barrier thin-film stack and also enveloping the edges of the substrate.

FIG. 2e is a simplified horizontal cross-section of the completed solar panel showing the attachment of the electrical connector to carry the output power.

FIG. 3 is a simplified horizontal cross-section of a convex-shaped, partially barrier coated border zone.

### DETAILED DESCRIPTION OF THE INVENTION

As shown in the drawings for purposes of illustration, the present invention is concerned with an improved solar panel, generally designated in the accompany drawings by the reference number 210. The improved solar panel 210 comprises, generally, a substrate 220 transparent to a range of operating wavelengths, a functional stack 230 capable of converting light into electricity on said substrate and having at least one electrical contact 240 with conductive connection tabs 250 coupled to each and defining a border zone 260 on the substrate around the perimeter of the functional stack 230, a barrier layer 270 comprised of a plurality of inorganic films on said substrate so as to cover at least a portion of said functional stack 230 and said border zone 260, an envelope layer 280 comprised of a plurality of polymer films on said substrate so as to cover at least a portion of said barrier layer 270, said border zone 260 and the edges of the substrate 220, and an electrical connector 290 connected to each of the conductive connection tabs 250.

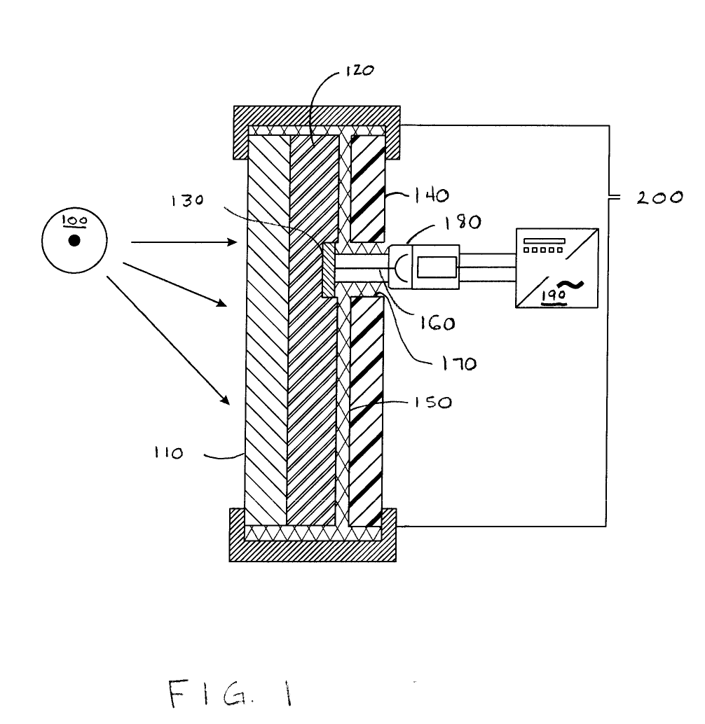

In accordance with the present invention, and as illustrated with respect to a preferred embodiment in FIGS. 1-3, this invention divides the many types of protection solar panels need between two stacks of protective coatings: a “barrier stack” or “barrier layer” 270 of inorganic films directly over the functional stack, and an “envelope stack” or “envelope layer” 280 of polymer layers over the barrier stack and extending over the edges of the substrate. The barrier stack protects the functional stack from moisture, chemicals, and internal stray electric fields. The envelope stack protects the entire solar panel—the substrate, functional stack, and barrier stack—from mechanical and thermal stress, shocks, abrasions, fire, external electric fields, weathering, and UV radiation. As will be pointed out in the preferred embodiment, all the forms of protection needed can be provided by a two-layer barrier stack and a two-layer envelope stack. However, the scope of this invention also extends to barrier and envelope stacks with more layers whose physical and chemical properties and protective capabilities are similar to those described here.

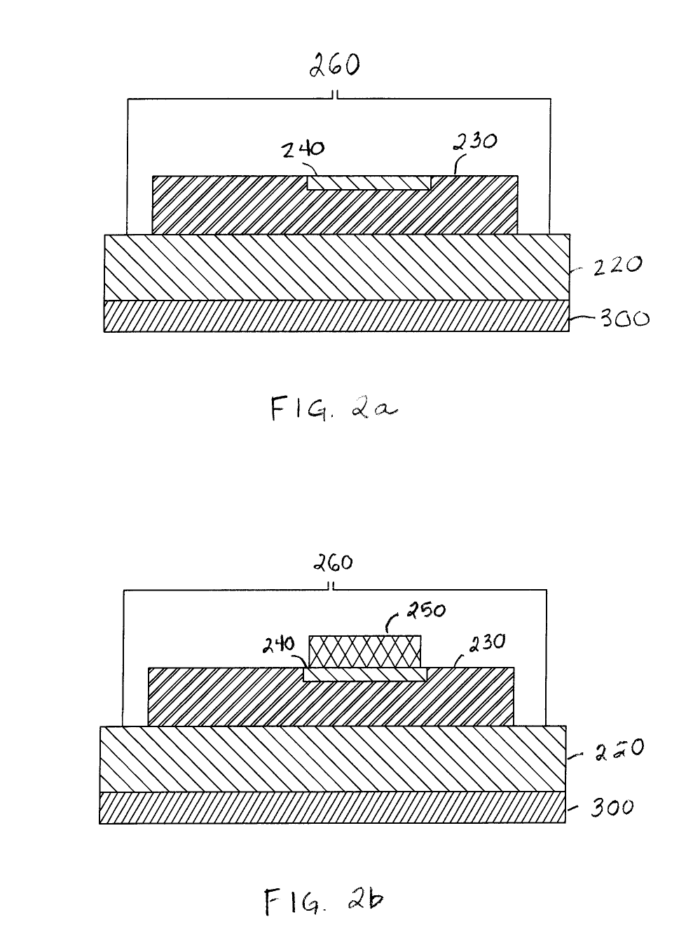

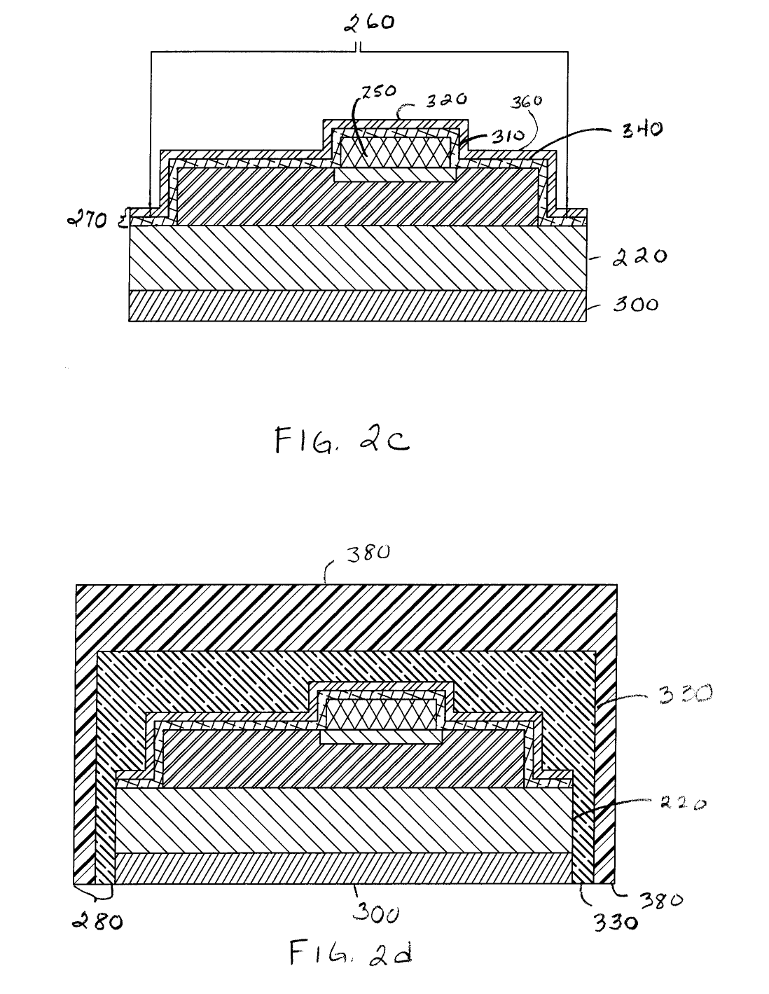

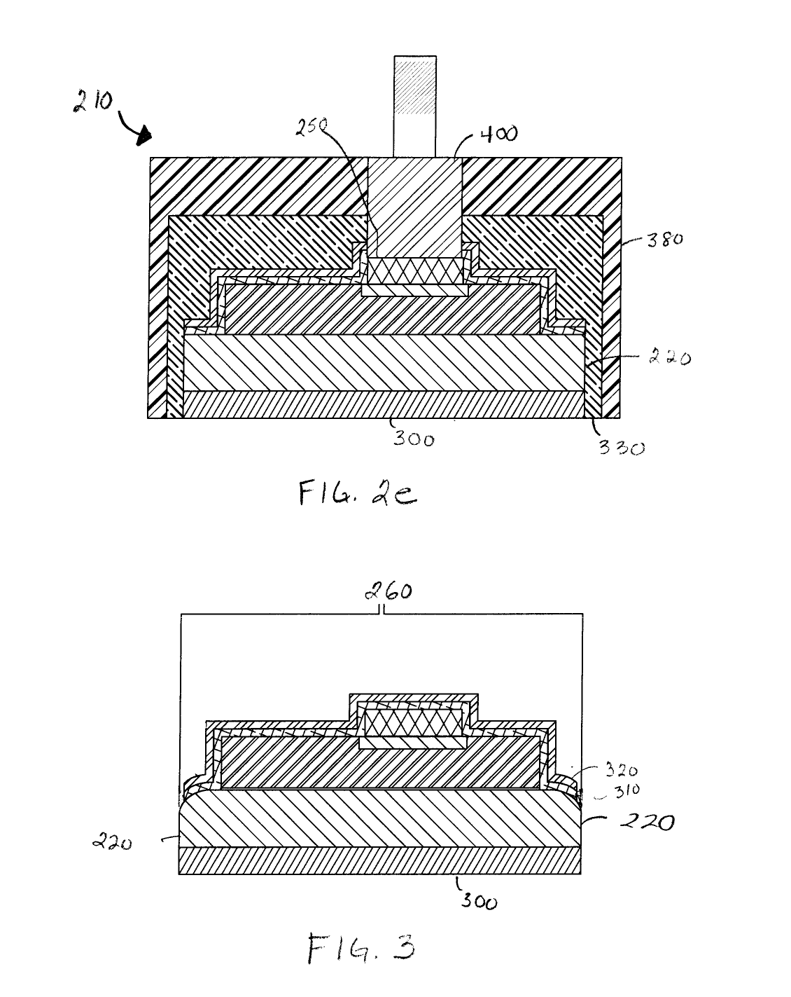

In the preferred embodiment, the solar panel is fabricated “front-to-back” by depositing and modifying layers of thin films on a glass substrate. As seen in FIG. 2a, glass substrate 220 eventually becomes the front (light-receiving) window of the finished panel. The front of substrate 220 may have a coating stack 300, which may include protective layers and optical layers to optimize transmission of the useful wavelengths. On the back of substrate 220 are the thin film layers that convert sunlight into electricity (the “functional stack”) 230. At least one electrical contact 240 is exposed on the back of functional stack 230; also exposed may be other semiconductor, metal, or dielectric materials. An uncoated border zone 260 is at least about 0.25 mm wide, preferably more than 1 mm wide between the outer edges of functional stack 230 and the outer edges of substrate 220. Border zone 260 can be created by masking off the edges while depositing or patterning the functional stack, or by removing that portion of the functional stack that extends into the border zone.

Next, as in FIG. 2b, connection tabs 250, made of electrically conductive materials, are bonded to each electrical contact 240 to form an electrical connection. Any suitable bonding method may be used.

Next, as in FIG. 2c, the barrier stack or barrier layer 270 of at least two electrically-insulating inorganic films (represented here as inner barrier film 310 and outer barrier film 320) is coated on the back surface of the panel, including border zone 260 and preferably including connection tabs 250. Connection tabs 250 may alternatively be at least partially masked so that at least a portion remains uncoated. Each inorganic film in the barrier stack is preferably between about 50 and about 2500 nanometers thick, but may be thicker in some embodiments where the coatings are resilient to stress. Any suitable method of applying the barrier films at temperatures below 170° C., such as vacuum deposition, sputter deposition, or plasma enhanced chemical vapor deposition (PECVD), may be used.

No matter how many barrier films are used, inner barrier film 310 (the layer of the barrier stack closest to the functional stack) is preferably a strong electrical insulator, chemically inert, highly corrosion-resistant, and as impermeable as possible to moisture, chemicals, and ions. The inner barrier film is the functional stack's most critical moisture and chemical barrier, and its main electrical insulation from ionic currents and other stray fields generated inside the panel. Because of the typical operating environments and other operating conditions for solar panels and other outdoor optoelectronics, the inner barrier film preferably retains these qualities over a wide range of temperature and humidity, after many temperature and humidity cycles and prolonged exposure to electric fields and solar-spectrum UV light. Silicon nitrides and silicon carbides, for instance, can satisfy these requirements. Ast et al. demonstrated that 100 nm of silicon nitride blocked out-diffusing ions beyond the range of secondary-ion mass spectroscopy (SIMS) detection, even after 8 hours of annealing at 900° C. Besides effectively excluding humidity, these materials have a very high electrical resistance, capable of blocking corrosion-accelerating ionic currents from the conductive portions of the underlying functional stacks. They can also be deposited with a low incidence of pinhole defects.

Also, no matter how many barrier films are used, outer barrier film 320 (film in the barrier stack farthest from the functional stack) preferably adheres very well to both the barrier film below it and an inner envelope layer 330 (the first layer of polymer that will be deposited above the outer barrier film 320). The outer barrier film is also preferably an electrical insulator (though it need not be as strong as the first-deposited layer), chemically inert, and corrosion-resistant, with very low permeability to moisture, chemicals, and ions (though it need not necessarily be as impermeable as the first-deposited layer). The outer barrier film serves largely as a coupling layer, keeping the barrier stack firmly sealed to the envelope stack. Because of the typical operating environments and other operating conditions for solar panels and other outdoor optoelectronics, the outer barrier film preferably retains these qualities over a wide range of temperature and humidity, after many temperature and humidity cycles and prolonged exposure to electric fields and solar-spectrum UV light. Silicon oxides, for instance, can satisfy these requirements. Silicon oxides with proper surface treatment, particularly silicon dioxide, adhere strongly to many inorganic materials and polymers, are chemically inert and corrosion-resistant, and perform acceptably as electrical insulators and barriers to moisture, chemicals, and ions. Like the silicon nitrides and carbides, silicon oxides can be deposited with a very low incidence of pinhole defects.

The two or more layers in the barrier stack can fulfill the various protective and structural requirements as a combination, so that no single material must meet all the functional stack's barrier needs. Another advantage of multiple layers is that each film in the barrier stack fills in and covers any defects in the layer beneath it, as shown in FIG. 2c. The barrier stack or layer substantially conforms to the underlying features and contours of the solar panel. If the surfaces to be coated are clean and smooth, pinholes in the barrier films are few and occur in random locations. Therefore, applying a plurality of inorganic layers ensures that any pinholes that do occur in individual coating layers are not aligned with each other to form a path of ingress for moisture or contaminants. As shown in FIG. 2c, pinhole defect 340 in inner barrier film 310 is filled in by outer barrier film 320 deposited above it. Conversely, any contaminant that enters pinhole defect 360 in outer barrier film 320 is blocked by intact inner barrier film 310 below it. Because all the films in the barrier stack are nonporous inorganic materials, the cumulative moisture protection of this barrier stack is more effective than prior-art designs that place polymer layers between inorganic layers.

Many parts of a solar panel's functional stack are vulnerable to moisture and chemical damage, including the transparent conductor deposited directly on the substrate, the active semiconductor layer(s) above the transparent conductor, and the combination of materials that form the back conductor and back reflector. The edges of the functional stack are particularly vulnerable because the interfaces between layers can provide paths of ingress for moisture and contaminants, especially if they are stressed or partially delaminated by repeated differential expansion and contraction resulting from the temperature cycles that are a consequence of outdoor exposure. Enhanced protection of the edges of these delicate films is the reason for creating border zone 260 around the edges of the substrate and coating barrier stack 310 and 320 on top of it. Moisture or contaminants that reach the edge of the border zone are blocked by an effective barrier thickness equal to the extent of the barrier stack into the border zone, which is many times thicker than the mere sum of all the barrier-film thicknesses. Therefore, even if small defects or chips occur at the edge of the barrier stack, moisture and contaminants are still virtually certain to be blocked by the remaining width of the barrier stack in the border zone. Nor are the barrier-stack layers likely to gradually delaminate in the field; their similarity of composition, unlike the alternating glass and polymer layers of the prior art, ensures strong adhesion, and a close match of thermal expansion coefficients, to each other and to glassy substrate surfaces.

Next, as in FIG. 2d, the envelope stack or envelope layer 280 or of at least two polymer films (represented in FIG. 2d by the inner envelope layer 330 and an outer envelope layer 380) is applied to the back and all the edges of the panel, including border zone 260 and preferably including connection tabs 250. Connection tabs 250 may alternatively be at least partially masked. Preferably, the polymer films are applied in liquid form, then cured to solid form with UV radiation or thermal heating below 200° C. Suitable polymers, such as acrylic, siloxane, urethane, polyester, epoxy, fluoropolymer, or their modified derivatives may be used. Each polymer film in the envelope stack is preferably between about 10 and about 250 microns thick—much thicker than the inorganic films in the barrier stack or layer.

No matter how many envelope layers are used, at least the inner envelope layer 330 (the polymer film nearest to the barrier stack) is preferably chosen for strong adhesion to the outer barrier film, high dielectric insulation strength, and enough flexibility to elastically absorb shocks, tension, compression, torsion, and the push-pull effects of differential thermal expansions of the other panel components, even at below-freezing temperatures. The inner envelope layer provides the bulk of the solar panel electrical insulation from sources outside the panel and resiliency to mechanical and thermal shock and stress. The effectiveness of the inner envelope layer is critical to the test performance of the solar panel under damp-heat (85° C. and 85% RH) and humid-freezing conditions.

Also, no matter how many envelope layers are used, outer envelope layer 380 (the polymer film farthest away from the barrier stack) is preferably chosen for strong adhesion to the polymer film directly beneath it and sufficient mechanical hardness to be substantially impervious to localized impacts (as from rocks or hailstones), localized pressure (as from icicles or branches), and abrasion (as from blowing sand). It should retard flame and withstand prolonged weathering. The outer envelope layer must also shield the layers beneath it from solar-spectrum UV radiation without harming itself through thermal or photon-absorption processes that adversely alter its mechanical or chemical structure.

Because of the typical operating environments and other operating conditions for solar panels and other outdoor optoelectronics, the envelope layers preferably retain their protective qualities over a wide range of temperature and humidity, after many temperature and humidity cycles and prolonged exposure to electric fields and ultraviolet light. As with the inorganic barrier layers, the plurality of envelope layers ensures that a defect or pinhole in a lower layer is covered by the layers above it, and a defect or pinhole in an upper layer will be blocked by the layers below it. The application of the envelope layers to the barrier stack also fills in any remaining pinhole defects in the outer barrier film. The envelope layer therefore substantially conforms to the underlying features and contours of the solar panel.

Applying the envelope stack to the edges of the solar panel protects the edges from chipping or cracking, thus eliminating the need for the separate frame required by prior-art solar panels. Any reliable method of applying these polymeric materials, such as slot-die coating, curtain coating, roll coating, or spray coating, may be used. Because these coatings, applied as liquid polymers, conform exactly to the contours of the barrier stack and substrate, they can potentially shield the delicate areas of the panel more effectively than a prior-art potted frame. Thus, all the required forms of protection are supplied to the panel, and the inner barrier layers are also protected from stresses and shocks that could create defects or other paths of ingress for moisture or contaminants.

As shown in FIG. 2e, electrical connectors 400 for transmitting the device output to the next component in line (for most solar panels, this is an inverter, a battery, or the terminal of another solar panel) are attached to the connection tabs 250. Enough of electrical connector 400 extends beyond the outer envelope layer 380 to enable connection and disconnection of a suitable mating connector in the field.

In the preferred embodiment, the electrical connector 400 is bonded to the connection tab 250 through the coating layers, by UWTI (ultrasonic welding through insulation) or a similar process. The UWTI process only removes coatings in the exact area of the bond, and allows some or all of them to be undisturbed prior to bonding. Minimizing disruption to the coatings minimizes the risk of compromising their protective performance near the connector. Potting material or a sealant can be added in the vicinity of the bond if needed. Alternatively, if the connector tabs were at least partially masked during the coating process, any suitable bonding method may be used. Otherwise, the coating may be selectively removed over the connector tabs, the connections for the inverter, battery, or connection with another solar panel may be bonded by any suitable method, and the connections may be potted to cover any gaps in the coating.

As shown in FIG. 3, border zone 260 of substrate 220 may be beveled, chamfered, or convex (FIG. 3) for additional protection from edge chipping. These alternate border-zone shapes may be imposed when the substrate is fabricated, or the shape of the border zone may be altered during or after removal of the functional stack from the border zone. To block ions from migrating out of the substrate surface, the barrier stack covers as much of the bevel, chamfer, or convex feature as is practical. As shown in FIG. 3, the barrier stack or layer substantially conforms to the contours of the border zone.

In another embodiment, the substrate may be a polymer that is transparent to the operating wavelengths. The same type of barrier stack and envelope stack described in the preferred embodiment above is known to adhere well to various transparent polymers. The polymer must be chosen so that its expected thermal-expansion coefficient and operating flexibility will not stress the glassy barrier layer to the point of short-term catastrophic damage or long-term fatigue that could compromise the barrier stack's performance.

In another embodiment, the functional stack includes a wafer of single-crystal or poly-crystalline silicon or another semiconductor, laminated or otherwise attached to a substrate, where the substrate is transparent to the operating wavelength.

From the foregoing, it is to be appreciated that this invention substantially eliminates expensive, heavy, potentially leaky backskins, backcaps, and frames of prior art solar panels, provides the protection a solar panel needs with a protective coating that can include as few as four layers, but may include more with properties similar to the described barrier stack or envelope stack.

Although particular embodiments of the invention have been described in detail for purposes of illustration, various modifications may be made without departing from the spirit and scope of the invention. Accordingly, the invention is not to be limited, except as by the appended claims.

1. An optoelectronic device, comprising:
a substrate transparent to a range of operating wavelengths;
a functional stack capable of converting light into electricity on said substrate and having at least one electrical contact with a conductive connection tab coupled to each and defining a border zone on the substrate between at least one edge of the functional stack and the at least one edge of the substrate;
a barrier layer comprised of a plurality of inorganic films on said substrate so as to cover at least a portion of said functional stack and said border zone;
an envelope layer comprised of a plurality of polymer films on said substrate so as to cover at least a portion of said barrier layer, said border zone and the edges of the substrate.
an electrical connector connected to each of the conductive connection tabs.

2. The device of claim 1, wherein the barrier layer and envelope layer substantially conform to the underlying features and contours.

3. The device of claim 1, wherein each of the polymer films in said envelope layer is thicker than each of said inorganic films in said barrier layer.

4. The device of claim 1, wherein at least one of the plurality of inorganic films substantially covers the edges of said functional stack.

5. The device of claim 1, wherein at least one of the plurality of polymer films substantially covers the edges of the barrier layer and substrate.

6. The device of claim 1, wherein the plurality of inorganic films comprises at least an inner barrier film closest to the functional stack and at least an outer barrier film closest to the envelope layer and the plurality of polymer films comprises at least an inner envelope layer closest to the outer barrier film and an outer envelope layer farthest from the outer barrier film.

7. The device of claim 1, wherein the border zone is beveled, chamfered, or convex.

8. The device of claim 1, wherein each of the plurality of inorganic films is between about 50 and about 2500 nanometers thick.

9. The device of claim 1, wherein each of the plurality of polymer films is between about 10 and about 250 microns thick.

10. The device of claim 1, wherein the border zone is at least about 0.25 mm wide.

11. The device of claim 6, wherein at least the inner and outer barrier films are highly electrically insulating, substantially chemically inert, substantially impermeable to moisture, chemicals, and ions, and substantially insensitive to long-term temperature and humidity fluctuations and prolonged exposure to electric fields and ultraviolet light, the inner barrier film also being substantially corrosion resistant.

12. The device of claim 11, wherein at least the inner barrier film is selected from the group consisting of a silicon carbide and a silicon nitride.

13. The device of claim 11, wherein at least the outer barrier film adheres to the adjacent inorganic barrier film and inner envelope layer to couple the barrier layer to the envelope layer.

14. The device of claim 11, wherein at least the outer barrier film comprises a silicon oxide.

15. The device of claim 11, wherein at least the inner envelope layer is electrically insulating, elastically absorbs mechanical shocks, mechanically relieves adjacent rigid materials from external compression, tension, bending, and torsion stresses, elastically responds to differential thermal expansion of the other materials in the device, and is substantially insensitive to long-term temperature and humidity fluctuations and prolonged exposure to electric fields and ultraviolet light.

16. The device of claim 11, wherein at least the outer envelope layer is mechanically hard and resistant to mechanical damage from localized impacts, locally concentrated pressure, and abrasion, substantially flame-retardant and resistant to prolonged weathering, and substantially blocks ultraviolet radiation from underlying materials without being substantially affected mechanically or chemically, such properties substantially insensitive to long-term temperature and humidity fluctuations and prolonged exposure to electric fields and ultraviolet light.

17. The device of claim 1, wherein the functional stack comprises at least one photovoltaic cell.

18. The device of claim 1, wherein the polymer films are comprised of a polymer selected from the group consisting of one or more of acrylic, siloxane, urethane, polyester, epoxy, fluoropolymer and modified derivatives thereof.

19. A method of protectively coating the back and edges of an optoelectronic device built as a functional stack on a transparent substrate, comprising the steps of:
creating a border zone of uncoated substrate between at least one edge of the functional stack and at least one edge of the transparent substrate;
attaching a conductive connection tab to each of one or more electrical contact portions of the functional stack;
applying a plurality of inorganic films over at least a portion of the functional stack, over at least a portion of the conductive connection tabs, and over at least a portion of the border zone; and
applying a plurality of polymer films over at least a portion of the plurality of inorganic films, over at least a portion of the conductive connection tabs, and over at least a portion of the edges of the substrate.

20. The method of claim 19, wherein creating the border zone comprises:
defining a border zone that extends a selected distance inward from each edge of the substrate, and
building the functional stack in a confined location that does not impinge on the border zone.

21. The method of claim 19, wherein creating the border zone comprises:
defining a border zone that extends a selected distance inward from each edge of the substrate, and
removing that portion of the functional stack which extends into the border zone.

22. The method of claim 19, wherein creating the border zone comprises altering the shape of the substrate within the border zone by removing a portion of the substrate.

23. The method of claim 19, wherein the plurality of polymer films are applied while in a liquid state, the method further comprising the step of allowing or assisting the liquid polymer films to harden to a solid state.

24. The method of claim 19, further comprising conductively coupling an electrical connector to each conductive connection tab.

25. The method of claim 24, wherein:
at least one polymer film is applied over the conductive connection tab, and conductively coupling the electrical connector comprises:
at least partially melting the at least one polymer film overlying the conductive connection tab,
pushing the electrical connector through the at least one polymer film to contact the conductive connection tab,
creating an electrical contact between the electrical connector and the conductive connection tab, and
allowing or assisting the at least one polymer film to return to a solid state.
